(19) United States
(12) Patent Application Publication
(10) Pub. No.: US 2018/0197760 A1
(43) Pub. Date: Jul. 12, 2018

(54) Dual PVD Chamber And Hybrid PVD-CVD Chambers

(71) Applicant: Applied Materials, Inc., Santa Clara, CA (US)

(72) Inventors: Deepak Jadhav, Karnataka (IN); Jallepally Ravi, San Ramon, CA (US); Manjunatha Koppa, Karnataka (IN); Vinod Konda Purathe, Karnataka (IN); Sandesh Yadamane, Bangalore (IN)

(21) Appl. No.: 15/863,295

(22) Filed: Jan. 5, 2018

Related U.S. Application Data
(60) Provisional application No. 62/443,692, filed on Jan. 7, 2017.

(51) Int. Cl. H01L 21/67; H01J 37/32; H01L 21/677; H01L 21/687

(52) U.S. Cl. CPC H01L 21/67167; H01J 37/32862; H01J 37/32357; H01J 37/32449; H01J 37/32816; H01J 37/32788; H01L 21/67742; H01L 21/68707; H01J 37/32743

(57) ABSTRACT

Processing platforms comprising a central transfer station having at least one robot and a dual chamber processing chamber connected to a side of the central transfer station through a gate valve are described. The dual chamber processing chamber comprises a first processing volume and a second processing volume connected to a shared vacuum pump.

### CROSS-REFERENCE TO RELATED APPLICATIONS

This application claims priority to U.S. Provisional Application No. 62/443,692, filed Jan. 7, 2017, the entire disclosure of which is hereby incorporated by reference herein.

### TECHNICAL FIELD

The present disclosure generally relates to methods and apparatus to deposit film stacks. In particular, the disclosure relates to methods and apparatus incorporating dual physical vapor deposition chamber and/or hybrid physical vapor deposition-chemical vapor deposition chamber.

### BACKGROUND

A new memory application employs stacks of TiN and SiO₂ films. The TiN films are deposited by physical vapor deposition (PVD) and the SiO₂ films are deposited by chemical vapor deposition (CVD). The memory application uses about 80 layers of PVD TiN and CVD SiO₂ deposited as a blanket film. There is a need for apparatus and methods to rapidly deposit the films.

### SUMMARY

One or more embodiments of the disclosure are directed to processing platforms comprising a central transfer station having at least one robot and a dual chamber processing chamber. The dual chamber processing chamber is connected to a side of the central transfer station through a gate valve. The dual chamber processing chamber comprises a first processing volume and a second processing volume connected to a shared vacuum pump.

Additional embodiments of the disclosure are directed to processing platforms comprising a central transfer station including a dual blade transfer robot, a first dual chamber processing chamber and a second dual chamber processing chamber. The first dual chamber processing chamber is connected to a first side of the central transfer station through a gate valve. The first dual chamber processing chamber comprises a first processing volume configured to perform a physical vapor deposition process and a second processing volume configured to perform a chemical vapor deposition process. The first dual chamber processing chamber includes a pump liner having two pump openings connected by a passage. The pump openings are aligned with the processing volumes. The first processing volume and the second processing volume are connected to a shared vacuum pump. The second dual chamber processing chamber is connected to a second side of the central transfer station through a gate valve. The second dual chamber processing chamber comprises a first processing volume configured to perform a physical vapor deposition process and a second processing volume configured to perform a chemical vapor deposition process. The second dual chamber processing chamber includes a pump liner having two pump openings connected by a passage. The pump openings are aligned with the processing volumes. The first processing volume and the second processing volume are connected to a shared vacuum pump.

Further embodiments of the disclosure are directed to processing platforms comprising a central transfer station having at least one robot and a dual chamber processing chamber connected to a side of the central transfer station through a gate valve. The dual chamber processing chamber comprises a first processing volume configured to perform a physical vapor deposition process and a second processing volume configured to perform a chemical vapor deposition process. The dual chamber processing chamber includes a pump liner having two pump openings connected to a passage with an isolation valve. A roughing pump is connected to the pump liner to decrease the pressure in the first processing volume and the second processing volume at the same time and a turbo-pump or cyro-pump is connected to the first processing volume to decrease the pressure of the first processing volume when the isolation valve is closed.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 shows a schematic cross-sectional view of a dual chamber processing chamber in accordance with one or more embodiment of the disclosure;

FIG. 2 shows a cross-sectional view of a pumping liner in accordance with one or more embodiment of the disclosure;

FIG. 3 shows a cross-sectional view of a pumping liner in accordance with one or more embodiment of the disclosure;

FIG. 4 shows a schematic side view of a dual chamber processing chamber in accordance with one or more embodiment of the disclosure;

FIG. 5 shows a partial schematic side view of a pumping liner in accordance with one or more embodiment of the disclosure; and

FIG. 6 shows a schematic view of a processing platform in accordance with one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

According to one or more embodiments, the method uses an atomic layer deposition (ALD) process. In such embodiments, the substrate surface is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap. As used in this specification and the appended claims, the terms “precursor”, “reactant”, “reactive gas” and the like are used interchangeably to refer to any gaseous species that can react with the substrate surface.

Embodiments of the disclosure are directed to apparatus and methods to deposit films in a cluster tool using twin chambers. The twin chambers can have two chemical vapor deposition (CVD) chambers, two physical vapor deposition (PVD) chambers or one each CVD and PVD chamber that share a single pump and/or gauge plate. Some embodiments advantageously provide processing chambers that can process two substrates at the same time. Some embodiments advantageously provide processing chambers that share a single pump to quickly evacuate two processing volumes at the same time. Some embodiments advantageously provide a dual chamber that shares a single gauge plate to measure the total pressure of two processing volumes at the same time.

The pump liner of some embodiments is advantageously designed to allow side-by-side pumping. A passage between the two process volumes to allow for the sharing of a single pump and/or single gauge plate. Some embodiments advantageously provide dual processing platforms to increase throughput for platforms that do not generally operate at pressures low enough for CVD or PVD processing.

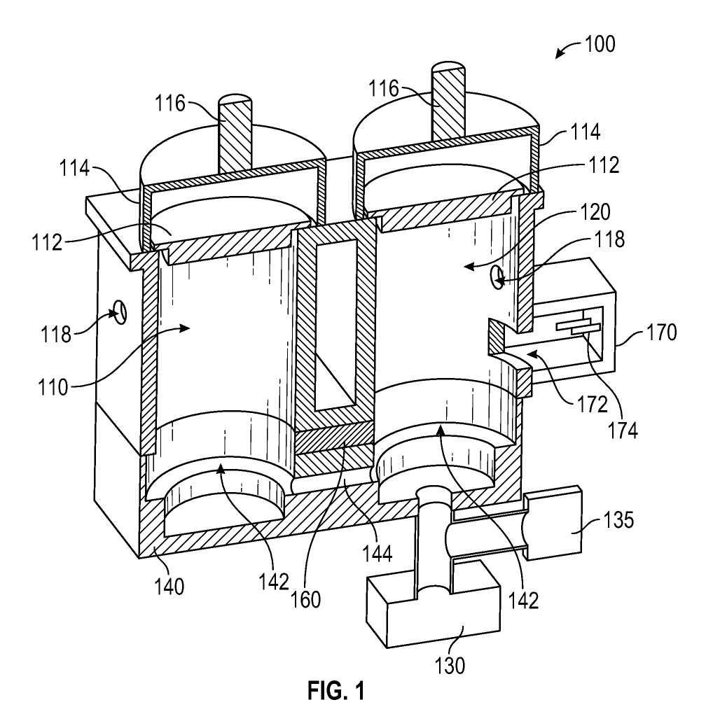

FIG. 1 shows a partial schematic cross-sectional view of a dual chamber processing chamber 100 in accordance with one or more embodiment of the disclosure. The dual chamber processing chamber 100 comprises a first processing volume 110 and a second processing volume 120 connected to a shared vacuum pump 130. Each of the first processing volume 110 and the second processing volume 120 in the embodiment of FIG. 1 is a physical vapor deposition chamber. Stated differently, the processing volumes can be configured to perform physical vapor depositions.

The physical vapor deposition chambers include any components that might be included with a stand-along PVD chamber. For example, each of the processing volumes 110, 120 can include a target 112 made of any suitable material. A power source can be connected to the target 112 or upper housing 114 through a suitable connection 116 (e.g., a coaxial RF feed line). A gas feed 118 can be connected to the processing volumes 110, 120 to allow a process gas to be flowed into the processing volume 110, 120. A suitable substrate support (not shown) is positioned within the processing volume 110, 120 to hold a substrate during deposition.

The target 112 of some embodiments is made from titanium or titanium nitride. In some embodiments, the target 112 comprises titanium and the process gas flowed through the gas feed 118 comprises nitrogen.

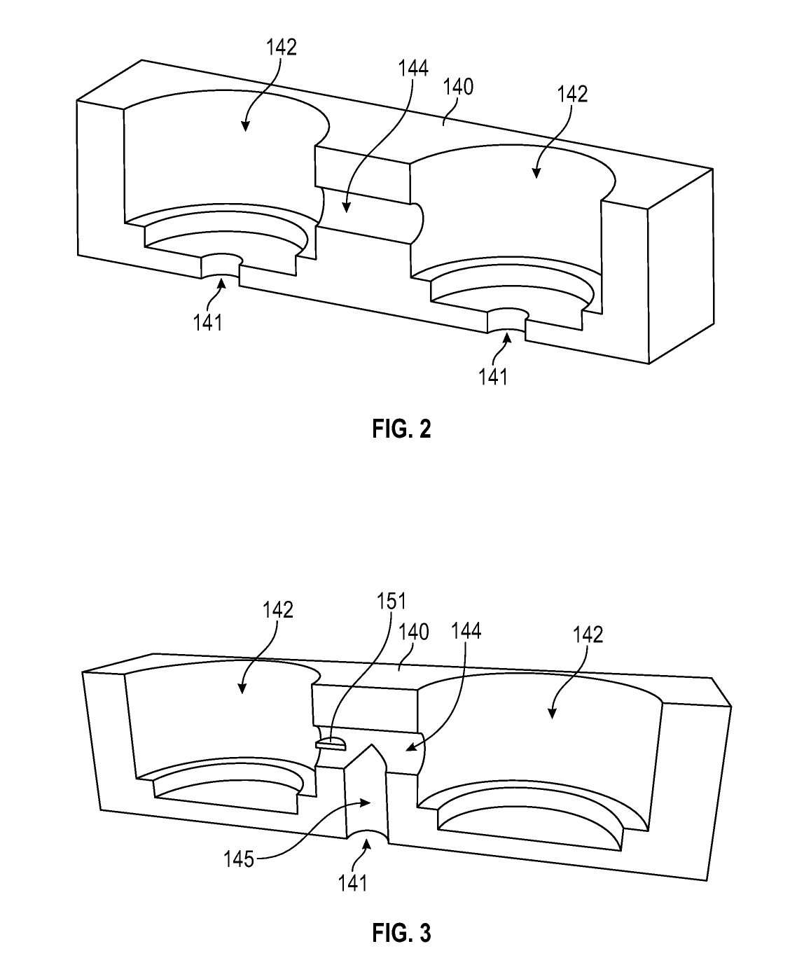

The dual chamber processing chamber 100 of some embodiments includes a pump liner 140 having two pump openings 142 connected by a passage 144. FIGS. 2 and 3 show cross-sections of alternate pump liners 140. The pump openings 142 are aligned with the processing volumes 110, 120 so that the processing volumes 110, 120 can be pumped down to low pressure. The passage 144 forms a fluid connection between the two pump openings 142.

The vacuum pump 130 can be connected to the pump liner 140 at various positions. In the embodiment shown in FIG. 1, the shared vacuum pump 130 is connected to the pump liner 140 at opening 142 aligned with the second processing volume 120. In FIG. 2, the pump liner 140 has two apertures 141 with each aperture 141 in fluid communication with an opening 142. In embodiments of this sort, the pump can be connected to either or both of the apertures 141 or different pumps can be connected to each aperture 141. For example, a roughing pump (e.g., a rotovane pump) can be connected to one aperture 141 and a lower pressure pump (e.g., cryo-pump, turbo pump, diffusion pump) can be connected to the other aperture 141. A valve (not shown) can be used to cut off communication between the pump and the openings 142.

In FIG. 3, the shared vacuum pump can be connected to the pump liner 140 at the passage 144 through a second passage 145. The pump can evacuate gases from each of the openings 142 through the passage 144 and second passage 145. Embodiments of this sort may have a more uniform gas conductance from each of the openings than the embodiment of FIG. 2. An isolation valve 151 can be positioned in passage 144, or adjacent passage 144 to isolate one of the openings 142 from the other opening 142. This might be useful where the processing volumes 110, 120 are configured for different processes that use different pressures.

Referring back to FIG. 1, some embodiments include a second pump 135 which can be separate from the pump 130 or in fluid communication with the pump 130 either by parallel or series connection. For example, a roughing pump might be positioned downstream of a diffusion pump, or a turbo pump might be in parallel with a roughing pump.

Some embodiments include a single gauge plate 160 positioned to measure the pressure, or other parameter, of the first process volume 110 and/or second process volume 120. The gauge plate 160 can have any suitable type of gauge including, but not limited to, monometers, thermistors or thermocouples.

Some embodiments of the disclosure include a disc garage 170 connected the process volume 110, 120 through an opening 172. The disc garage 170 can be used to hold a sacrificial wafer that can be moved into or out of the processing volume 120 using an actuator 174 to clean the target 112. For example, between processes, the sacrificial wafer can be moved through the opening 172 from the garage 170 to a processing position within the processing volume 120. A plasma can be ignited within the processing volume 120 to sputter off the surface of the target 112. After cleaning, the sacrificial wafer can be moved back through the opening 172 and stored in the garage 170 until cleaning is performed again.

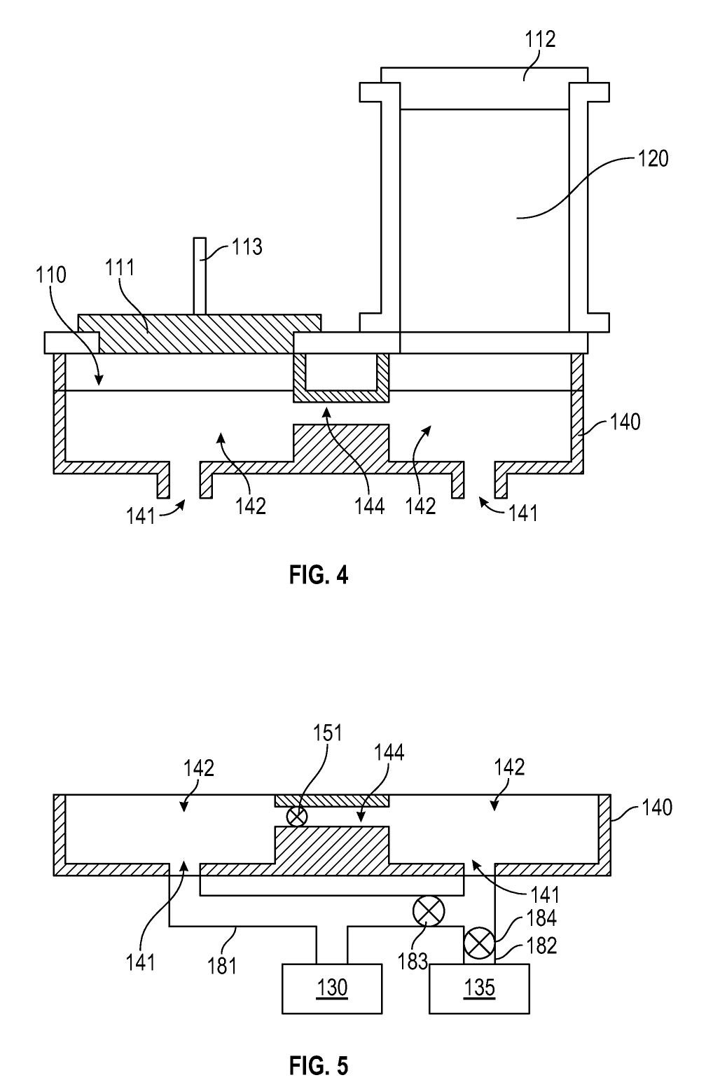

FIG. 4 shows a schematic cross-sectional view of another embodiment of the disclosure in which the first processing volume 110 is configured to perform a chemical vapor deposition process and the second processing volume 120 is configured to perform a physical vapor deposition process. While the embodiment shown has the CVD chamber on the left as the first processing volume 110 and the PVD chamber on the right as the second processing volume 120, those skilled in the art will understand that this is merely representative of one possible arrangement and should not be taken as limiting the scope of the disclosure. The CVD chamber can include any components used with chemical vapor deposition processing including, but not limited to, showerheads 111, gas inlet line(s) 113, plasma sources, lamps, heaters, substrate supports.

In some embodiments, the shared pump 130 is connected to the pump liner 140 at the opening 142 aligned with the second processing volume 120 and a second pump 135 is connected to the opening 142 aligned with the first processing volume 110. In the embodiment shown in FIG. 5, the shared pump 130 is connected to both the first processing volume 110 and the second processing volume 120 through conduit 181. The second pump 135 is connected to at least the second processing volume 120 through conduit 182. Valves 183, 184 can be positioned along conduit 181 and/or conduit 182 to control pumping. In use, shared pump 130 can be used to decrease the pressure in the processing volumes 110, 120 to a predetermined level. At that point, valve 183 can be closed and valve 184 opened and the second pump 135 can be used to lower the pressure in one or more of the processing volumes 110, 120. The pump 130 could be disengaged and the second pump 135 can take over or the pumping levels to each of the volumes can be different after the predetermined pressure is reached. This might be particularly useful where one processing volume is a CVD chamber and the other is a PVD chamber which may operate at much lower pressure than a CVD process. Other valves (not shown) can be included along conduit 181 to isolate the pump 130 from the conduit 181 or the processing volumes from the pump 130. Additionally, isolation valve 151 can be opened or closed to isolate the processing volumes from each other.

In some embodiments, the shared vacuum pump 130 is a roughing pump which can lower the pressure in the processing volumes to a first level. The second pump 135 can be a lower pressure pump (e.g., a cryo-pump or turbo pump) which can lower the pressure to a second level that is lower than the first level. For example, the roughing pump may lower the pressure to about 10⁻³ Torr and the cryo-pump may lower the pressure to about 10⁻⁸ Torr. In some embodiments, the pressure in the first processing volume 110 and the second processing volume 120 is maintained at a suitable pressure for physical vapor deposition processes. In some embodiments, the pressure in the first processing volume 110 and the second processing volume 120 can be lowered to a base pressure in the range of about 10⁻⁵ Torr to about 10⁻¹⁰ Torr, or in the range of about 10⁻⁶ Torr to about 10⁻⁸ Torr. In some embodiments, one or more of the pumps are configured to maintain a base pressure in the processing volume of less than or equal to about 10⁻⁵, 10⁻⁶, 10⁻⁷ or 10⁻⁸ Torr. The skilled artisan will recognize that the base pressure of the processing volume is not necessarily the same as the operating pressure during plasma processing.

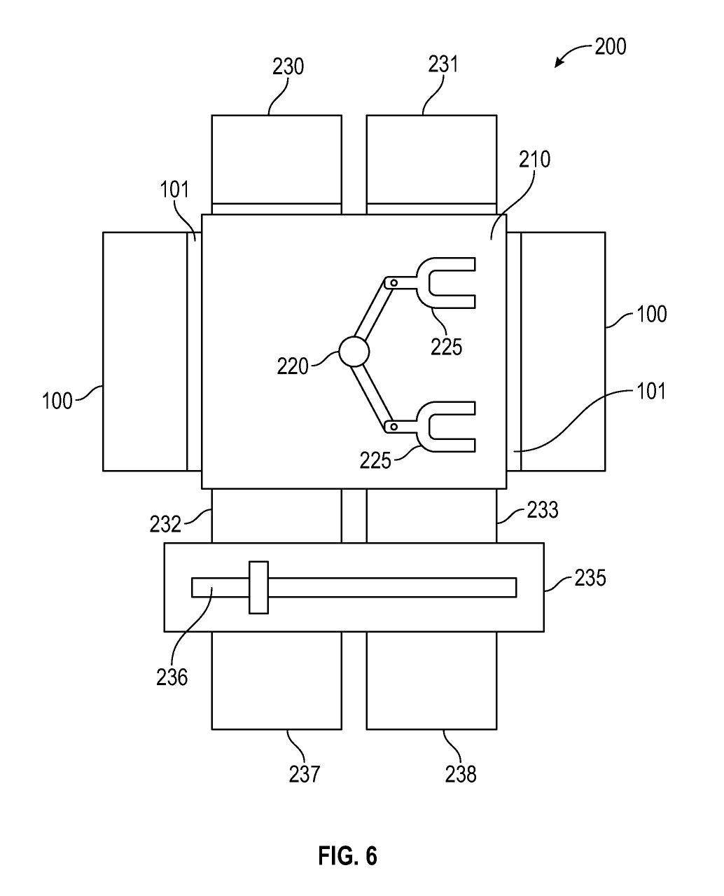

FIG. 6 shows a schematic view of a processing platform 200 in accordance with one or more embodiment of the disclosure. A central transfer station 210 has at least one robot 220 positioned within. The robot 220 can have a single blade 225 or can have dual blades 225 (as shown). The dual blades 225 can move together or separately.

The central transfer station of some embodiments has four sides. The sides can be straight or curved. In some embodiments, the central transfer station is configured to have two processing chambers on each side to accommodate a total of eight connection points. The embodiment shown has two dual chamber processing chambers 100 connected the central transfer station 210 with each dual chamber processing chamber 100 occupying two connection points. The dual chamber processing chambers 100 are connected to the central transfer station through a gate valve 101. The gate valve can be sized so that both process volumes are accessible at the same time, or can be individual so that each process volume has a separate gate valve connecting to the central transfer station 210.

The central transfer station of some embodiments is maintained at a relatively high pressure. For example, the central transfer station of some embodiments is configured to be maintained at a pressure down to about 1 Torr, 0.1 Torr, 0.01 Torr, 10⁻³ Torr, 10⁻⁴ Torr, 10⁻⁵ Torr or 10⁻⁶ Torr. In some embodiments, the central transfer station is configured to operate at pressures one, two, three, four, five or six orders of magnitude greater pressure than the processing volumes are configured to operate at. The use of the shared pump with the dual chambers can greatly increase throughput of this type of configuration by allowing two wafers to be processed at the same time.

The processing platform 200 shown in FIG. 6 includes additional process chambers 230, 231 connected to the central transfer station 210. Two pass-through chambers 232, 233 can be used to move wafers from the factory interface 235 to the central transfer station 210. The pass-through chambers 232, 233 can be used to pre-heat, cool, treat, clean, etc., the wafers coming into the transfer chamber or leaving the transfer chamber. The factory interface can include a robot 236 that moves wafers to and from load lock chambers 237, 238.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A processing platform comprising:
a central transfer station having at least one robot; and
a dual chamber processing chamber connected to a side of the central transfer station through a gate valve, the dual chamber processing chamber comprising a first processing volume and a second processing volume connected to a shared vacuum pump, the shared vacuum pump maintaining a base pressure less than or equal to about 10⁻⁵ Torr in one or more of the first processing volume or the second processing volume.

2. The processing platform of claim 1, wherein the first processing volume and the second processing volume are configured to perform physical vapor depositions.

3. The processing platform of claim 2, wherein each of the first processing volume and the second processing volume includes a target comprising titanium.

4. The processing platform of claim 3, wherein the dual chamber processing chamber includes a pump liner having two pump openings connected by a passage, the pump openings aligned with the processing volumes, the passage forming fluid connection between the two pump openings.

5. The processing platform of claim 4, wherein the shared vacuum pump is connected to the pump liner at one or both of the pump openings.

6. The processing platform of claim 4, wherein the shared vacuum pump is connected to the pump liner at the passage.

7. The processing platform of claim 1, wherein the first processing volume is configured perform physical vapor deposition and the second processing volume is configured to perform chemical vapor deposition.

8. The processing platform of claim 7, wherein the processing volume configured to perform physical vapor deposition includes a target comprising titanium.

9. The processing platform of claim 7, wherein the dual chamber processing chamber includes a pump liner having two pump openings connected by a passage, the pump openings aligned with the processing volumes, the passage forming fluid connection between the two pump liners.

10. The processing platform of claim 9, wherein the shared vacuum pump is connected to the pump liner at one or both of the pump openings.

11. The processing platform of claim 9, wherein the shared vacuum pump is connected to the pump liner at the passage.

12. The processing platform of claim 9, wherein the shared vacuum pump is connected to the pump liner at the opening aligned with the second processing volume and a second pump is connected to the opening aligned with the first processing volume.

13. The processing platform of claim 12, wherein the shared vacuum pump is a roughing pump and the second pump is one or more of a cryo-pump or a turbo-pump.

14. The processing platform of claim 13, further comprising an isolation valve positioned to isolate the first processing volume from the second processing volume.

15. The processing platform of claim 1, wherein the central transfer station is maintained at a relatively high pressure.

16. The processing platform of claim 15, wherein the central transfer station has four sides.

17. The processing platform of claim 16, wherein at least two sides of the central transfer station are connected to a separate dual chamber processing chamber.

18. The processing platform of claim 17, wherein the at least one robot has two transfer blades to move two wafers at the same time so that wafers can be placed in the first processing volume and the second processing volume at the same time.

19. A processing platform comprising:
a central transfer station including a dual blade transfer robot;
a first dual chamber processing chamber connected to a first side of the central transfer station through a gate valve, the first dual chamber processing chamber comprising a first processing volume configured to perform a physical vapor deposition process and a second processing volume configured to perform a chemical vapor deposition process, the first dual chamber processing chamber including a pump liner having two pump openings connected by a passage, the pump openings aligned with the processing volumes, the first processing volume and the second processing volume connected to a shared vacuum pump, the shared vacuum pump maintaining a base pressure in the first processing volume and the second processing volume less than or equal to about 10⁻⁵ Torr; and
a second dual chamber processing chamber connected to a second side of the central transfer station through a gate valve, the second dual chamber processing chamber comprising a first processing volume configured to perform a physical vapor deposition process and a second processing volume configured to perform a chemical vapor deposition process, the second dual chamber processing chamber including a pump liner having two pump openings connected by a passage, the pump openings aligned with the processing volumes, the first processing volume and the second processing volume connected to a shared vacuum pump, the shared vacuum pump maintaining a base pressure in the first processing volume and the second processing volume less than or equal to about 10⁻⁵ Torr.

20. A processing platform comprising:
a central transfer station having at least one robot; and
a dual chamber processing chamber connected to a side of the central transfer station through a gate valve, the dual chamber processing chamber comprising a first processing volume configured to perform a physical vapor deposition process and a second processing volume configured to perform a chemical vapor deposition process, the dual chamber processing chamber including a pump liner having two pump openings connected to a passage with an isolation valve, a roughing pump is connected to the pump liner to decrease the pressure in the first processing volume and the second processing volume at the same time and a turbo-pump or cyro-pump is connected to the first processing volume to decrease the pressure of the first processing volume when the isolation valve is closed, the turbo-pump or cyro-pump configured to maintain a base pressure in the first processing volume at less than or equal to about 10⁻¹⁵ Torr.
